(19) United States
(12) Patent Application Publication
(10) Pub. No.: US 2021/0328070 A1
(43) Pub. Date: Oct. 21, 2021

(54) THIN FILM TRANSISTOR SUBSTRATE AND PREPARATION METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Letao ZHANG, Shenzhen (CN); Liangfen ZHANG, Shenzhen (CN); Xiaoxing ZHANG, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/617,516

(22) PCT Filed: Nov. 6, 2019
(86) PCT No.: PCT/CN2019/115847

§ 371 Date: Nov. 27, 2019

(51) Int. Cl. H01L 29/786; H01L 27/32; H01L 29/66

(52) U.S. Cl. CPC H01L 29/78633; H01L 29/66742; H01L 27/3272

(57) ABSTRACT

A thin film transistor substrate and a preparation method thereof are provided. The thin film transistor substrate includes a substrate layer, a light shielding layer, a buffer layer, an active layer, a gate insulating layer, a gate layer, an interlayer dielectric layer, a source/drain layer, a passivation layer, and a pixel electrode layer, which are sequentially disposed, wherein the light shielding layer is formed by a nano core-shell structure, and the nano core-shell structure includes a nano core and a shell.

### FIELD OF INVENTION

The present disclosure relates to the display panel technology field, and in particular, relates to a thin film transistor substrate and a preparation method thereof.

### BACKGROUND OF INVENTION

Active-matrix organic light-emitting diode (AMOLED) technology is the development trend of the panel industry. Compared with liquid crystal displays (LCDs), OLEDs have the advantages of simplified structure, wider color gamut, and faster response times.

In the pixel design of AMOLED, a pixel circuit comprised of a top gate self-aligned amorphous oxide TFT is generally used to drive the OLEDs to emit light. However, amorphous oxides are very sensitive to short-wavelength light, and a threshold voltage of the device is reduced by the action of light. Therefore, luminous intensity of the OLEDs is seriously affected. When a backing plate is fabricated, a metal light shielding layer is first deposited to protect the TFT device from bottom ambient light.

Referring to FIG. 1, a schematic view of a conventional thin film transistor substrate is illustrated. The thin film transistor substrate includes a substrate layer 100, a metal light shielding layer 11, a buffer layer 12, an active layer 13, a gate insulating layer 14, a gate layer 15, an interlayer dielectric layer 16, a drain electrode 171, a source electrode 172, a passivation layer 18, and a pixel electrode layer 19, which are sequentially disposed. As the metal light shielding layer 11 does not absorb short-wavelength light, short-wavelength light will be reflected between the gate layer 15 and the metal light shielding layer 11, resulting in threshold voltage being negatively biased.

In addition, in order to prevent the coupling effect of the overlapping capacitance of the metal light shielding layer 11 and the drain electrode 171, a hole is formed in the buffer layer 12, and the source electrode 172 connects to the metal light shielding layer 11. This will introduce two additional yellow light processes to increase the manufacturing cost of the OLED backplane.

As a result, it is necessary to provide a thin film transistor substrate to solve the problems existing in the conventional technologies, as described above.

### SUMMARY OF INVENTION

An object of the present disclosure is to provide a thin film transistor substrate, which can solve the problem of the coupling effect of the overlapping capacitance between a metal light shielding layer and a drain in the prior art.

To achieve the above object, the present disclosure provides a thin film transistor substrate, which includes a substrate layer, a light shielding layer, a buffer layer, an active layer, a gate insulating layer, a gate layer, an interlayer dielectric layer, a source/drain layer, a passivation layer, and a pixel electrode layer that are sequentially disposed, wherein the light shielding layer is formed by a nano core-shell structure, and the nano core-shell structure includes a nano core and a shell.

In one embodiment of the present disclosure, the nano core is a narrow band-gap semiconductor material, and the shell is an insulating dielectric material.

In one embodiment of the present disclosure, a band gap of the nano core is less than 2.5 eV.

In one embodiment of the present disclosure, the material of the nano core includes one of indium arsenide and indium phosphide.

In one embodiment of the present disclosure, a diameter range of the nano core is from 5 to 1000 nm.

In one embodiment of the present disclosure, the material of the shell includes one of silicon oxide and aluminum oxide.

In one embodiment of the present disclosure, a thickness range of the shell is from 3 to 200 nm.

In one embodiment of the present disclosure, the buffer layer completely covers the light shielding layer, the buffer layer is an insulating layer, and the arrangement is such that the buffer layer completely isolates the light shielding layer from the active layer.

In one embodiment of the present disclosure, the light shielding layer of a nano core-shell structure completely covers the active layer. The active layer is very sensitive to short-wavelength light, and the arrangement enables the light shielding layer of the nano core-shell structure to completely block the light that is incident from the substrate in one direction.

In one embodiment of the present disclosure, the substrate layer is one of a glass substrate and a flexible substrate.

In one embodiment of the present disclosure, the material of the buffer layer includes one of silicon oxide, silicon nitride, and aluminum oxide.

In one embodiment of the present disclosure, the material of the active layer includes one of indium gallium zinc oxide, indium zinc oxide, and indium zinc tin oxide.

In one embodiment of the present disclosure, the material of the gate insulating layer includes one of silicon oxide, silicon nitride, and aluminum oxide.

In one embodiment of the present disclosure, the material of the source/drain layer includes one of molybdenum, aluminum, copper, and titanium.

In one embodiment of the present disclosure, the material of the interlayer dielectric layer includes one of silicon oxide, silicon nitride, and aluminum oxide.

In one embodiment of the present disclosure, the material of the passivation layer includes one of silicon oxide, silicon nitride, and aluminum oxide.

To achieve another object, the present disclosure provides a preparation method of the thin film transistor substrate, and the preparation method comprises steps of: step S1: providing a substrate and disposing a light shielding layer of a nano core-shell structure; step S2: placing the substrate and the light shielding layer of the nano core-shell structure in a vacuum for annealing; step S3: disposing a buffer layer on the light shielding layer of the nano core-shell structure; step S4: sequentially disposing an active layer, a gate insulating layer and a gate layer on the buffer layer, and conducting a non-channel region of a pattern of the active layer; step S5: disposing an interlayer dielectric layer, and providing a first via hole on the interlayer dielectric layer; step S6: disposing a source/drain layer, and forming a pattern of the source/drain layer after etching; step S7: disposing a passivation layer, and providing a second via hole on the passivation layer; and step S8: disposing a pixel electrode layer, and forming a pixel electrode by etching.

In one embodiment of the present disclosure, a pressure range of the vacuum is from 10⁻⁴ to 10³ Pa.

In one embodiment of the present disclosure, a temperature range for annealing is from 100 to 500° c.

In one embodiment of the present disclosure, the buffer layer is disposed by adopting a plasma enhanced chemical vapor deposition method or a sputtering method.

In one embodiment of the present disclosure, the gate insulating layer is disposed by adopting a plasma enhanced chemical vapor deposition method or a sputtering method.

In one embodiment of the present disclosure, the interlayer dielectric layer is disposed by adopting a plasma enhanced chemical vapor deposition method or a sputtering method.

In one embodiment of the present disclosure, the passivation layer is disposed by adopting a plasma enhanced chemical vapor deposition method or a sputtering method.

Compared with the prior art, the beneficial effects of the present disclosure are that the present disclosure provides a thin film transistor substrate and a preparation method thereof. The light shielding layer is formed by a nano core-shell structure, wherein the light shielding layer of a nano core-shell structure has poor conductivity and does not have a capacitive coupling effect with the source/drain layer, thereby reducing the number of masks and reducing the cost. In addition, the light shielding layer of a nano core-shell structure can also absorb short-wavelength light and convert short-wavelength light into long-wavelength light. The short-wavelength leakage light does not reflect between the gate layer and the light shielding layer to reduce the threshold voltage negative bias caused by multiple reflections of leakage light in the active layer.

### DESCRIPTION OF DRAWINGS

In order to more clearly illustrate technical solutions in embodiments of the present disclosure, the drawings used in the description of the embodiments will be briefly introduced below. Obviously, the drawings in the following description are only some embodiments of the present disclosure, and those skilled in the art can obtain other drawings according to these drawings without any creative effort.

FIG. 1 is a schematic view of a conventional thin film transistor substrate.

FIG. 2 is a schematic view of a thin film transistor substrate according to an embodiment 1 of the present disclosure.

FIG. 3 is a flowchart of a preparation method of the thin film transistor substrate according to the embodiment 1 of the present disclosure.

FIG. 4 is a schematic view of the thin film transistor substrate in a step S1 of the preparation method according to the embodiment 1 of the present disclosure.

FIG. 5 is a schematic view of the thin film transistor substrate in a step S3 of the preparation method according to the embodiment 1 of the present disclosure.

FIG. 6 is a schematic view of the thin film transistor substrate in a step S4 of the preparation method according to the embodiment 1 of the present disclosure.

FIG. 7 is a schematic view of the thin film transistor substrate in a step S5 of the preparation method according to the embodiment 1 of the present disclosure.

FIG. 8 is a schematic view of the thin film transistor substrate in a step S6 of the preparation method according to the embodiment 1 of the present disclosure.

FIG. 9 is a schematic view of the thin film transistor substrate in a step S7 of the preparation method according to the embodiment 1 of the present disclosure.

FIG. 10 is a schematic view of the thin film transistor substrate in a step S8 of the preparation method according to the embodiment 1 of the present disclosure.

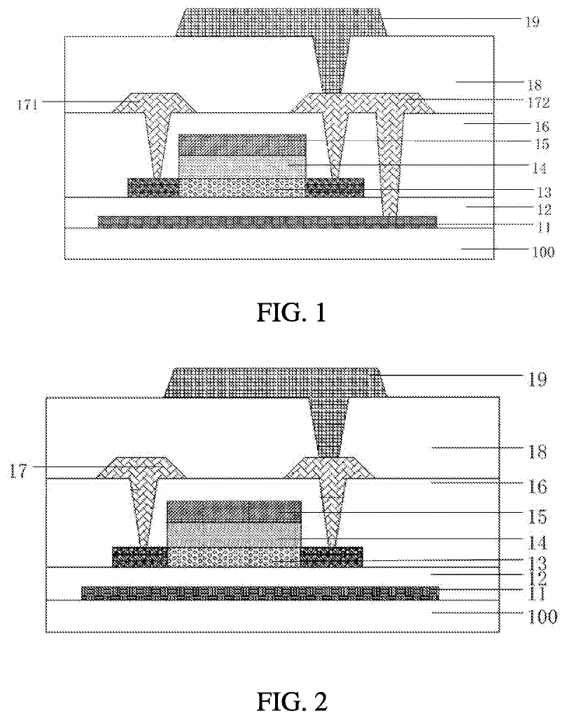

### DETAILED DESCRIPTION OF PREFERRED EMBODIMENTS

The technical proposals and the advantages of the embodiments of the present disclosure are clearly and completely described in the following with reference to the attached drawings in the embodiments of the present disclosure. Obviously, the embodiments illustrated are only one part of the embodiments of the present disclosure, but are not all the embodiments. All the other embodiments obtained by those skilled in the art on the basis of the embodiments of the present disclosure without providing creative labor shall be all within the scope of protection of the present disclosure.

### Embodiment 1

Referring to FIG. 2, a schematic view of a thin film transistor substrate according to an embodiment 1 of the present disclosure is illustrated. A thin film transistor substrate is provided in the present embodiment. The thin film transistor substrate includes a substrate layer 100, a light shielding layer 11, a buffer layer 12, an active layer 13, a gate insulating layer 14, a gate layer 15, an interlayer dielectric layer 16, a source/drain layer 17, a passivation layer 18, and a pixel electrode layer 19, which are sequentially disposed.

The light shielding layer 11 is formed by a nano core-shell structure, and the nano core-shell structure includes a nano core and a shell, wherein the nano core is a narrow band-gap semiconductor material, and the shell is an insulating dielectric material.

A band gap of the nano core is less than 2.5 eV, and a diameter range of the nano core is from 5 to 1000 nm, wherein a material of the nano core is indium arsenide or indium phosphide, which is not limited.

A thickness range of the shell is from 3 to 200 nm, and a material of the shell is silicon oxide or aluminum oxide, which is not limited.

The buffer layer 12 completely covers the light shielding layer 11, the buffer layer 12 is an insulating layer, and the arrangement is such that the buffer layer 12 completely isolates the light shielding layer 11 from the active layer 13 to prevent the light shielding layer 11 from contacting the active layer 13.

The light shielding layer 11 of a nano core-shell structure completely covers the active layer 13. The active layer 13 is very sensitive to short-wavelength light, and the arrangement enables the light shielding layer 11 of the nano core-shell structure to completely block the light that is incident from the substrate in one direction. The light shielding layer 11 of a nano core-shell structure can also absorb short-wavelength leakage light and convert short-wavelength leakage light into long-wavelength light. The long-wavelength light is reflected in the active layer 13 and is attenuated as the number of reflections increases, thereby not affecting the threshold voltage shift of devices.

In other embodiments, a material of the substrate layer 100 is one of a glass substrate or a flexible substrate. A material of the buffer layer 12 includes one of silicon oxide, silicon nitride, or aluminum oxide. A material of the active layer 13 includes one of indium gallium zinc oxide, indium zinc oxide, or indium zinc tin oxide. A material of the gate insulating layer 14 includes one of silicon oxide, silicon nitride, or aluminum oxide. A material of the source/drain layer 17 includes one of molybdenum, aluminum, copper, or titanium. A material of the interlayer dielectric layer 16 includes one of silicon oxide, silicon nitride, or aluminum oxide. A material of the passivation layer 18 includes one of silicon oxide, silicon nitride, or aluminum oxide.

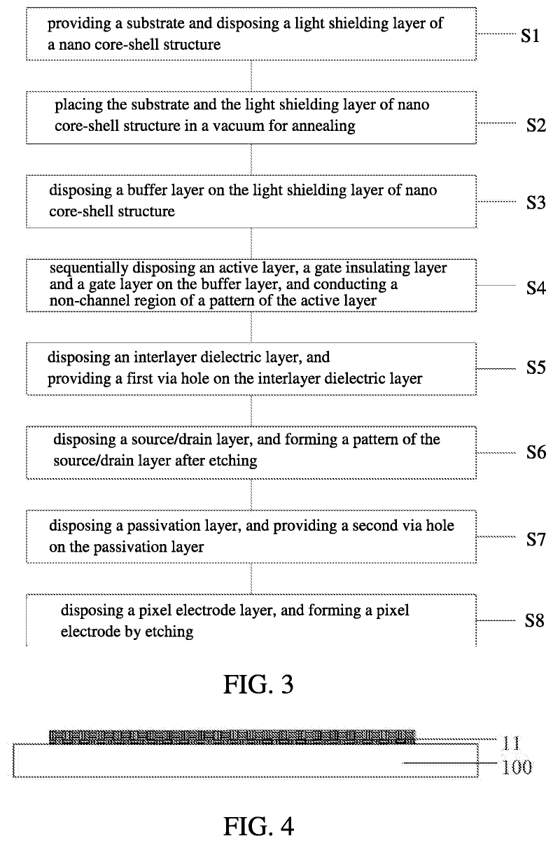

Referring to FIG. 3, a flowchart of a preparation method of the thin film transistor substrate according to the embodiment 1 of the present disclosure is illustrated. The embodiment further provides a preparation method of the thin film transistor substrate, and the preparation method comprises the following steps.

Referring to FIG. 4, a schematic view of the thin film transistor substrate in a step S1 of the preparation method according to the embodiment 1 of the present disclosure is illustrated.

In step S1: providing a substrate 100 and disposing a light shielding layer 11 of a nano core-shell structure on the substrate 100.

The light shielding layer 11 of the nano core-shell structure adopts one of an inkjet printing method or a direct coating method.

A nano core of the nano core-shell structure is a narrow band-gap semiconductor material, and a shell of the nano core-shell structure is an insulating dielectric material. A band gap of the nano core is less than 2.5 eV, and a diameter range of the nano core is from 5 to 1000 nm, wherein a material of the nano core includes indium arsenide or indium phosphide, which is not limited.

A thickness range of the shell is from 3 to 200 nm, and a material of the shell is silicon oxide or aluminum oxide, which is not limited.

In step S2: placing the substrate 100 and the light shielding layer 11 of the nano core-shell structure in a vacuum for annealing to completely evaporate the organic solvent of the light shielding layer 11 of the nano core-shell structure.

A pressure range of the vacuum is from 10⁻⁴ to 10³ Pa, and a temperature range for annealing is from 100 to 500° C.

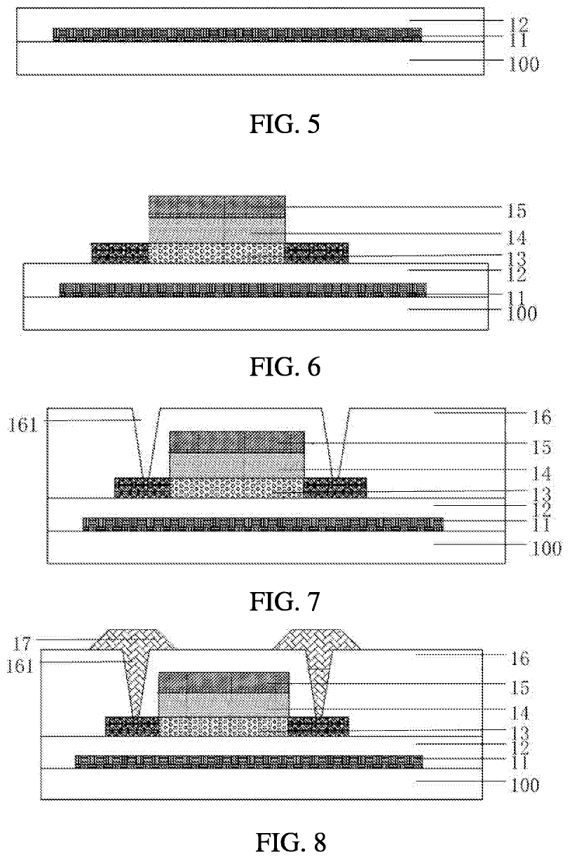

Referring to FIG. 5, a schematic view of the thin film transistor substrate in a step S3 of the preparation method according to the embodiment 1 of the present disclosure is illustrated.

In step S3: disposing a buffer layer 12 on the light shielding layer 11 of the nano core-shell structure.

The buffer layer 12 is disposed by adopting a plasma enhanced chemical vapor deposition method or a sputtering method, and the buffer layer 12 completely covers the light shielding layer 11.

Referring to FIG. 6, a schematic view of the thin film transistor substrate in a step S4 of the preparation method according to the embodiment 1 of the present disclosure is illustrated.

In step S4: sequentially disposing an active layer 13, a gate insulating layer 14, and a gate layer 15 on the buffer layer 12, and conducting a non-channel region of a pattern of the active layer 13.

The gate insulating layer 14 is disposed by adopting a plasma enhanced chemical vapor deposition method or a sputtering method. The light shielding layer 11 completely covers the active layer 13. The active layer 13 is very sensitive to short-wavelength light, and the arrangement enables the light shielding layer 11 of the nano core-shell structure to completely block the light that is incident from the substrate in one direction. The light shielding layer 11 of a nano core-shell structure can also absorb short-wavelength leakage light and convert short-wavelength leakage light into long-wavelength light. The long-wavelength light is reflected in the active layer 13 and is attenuated as the number of reflections increases, thereby not affecting the threshold voltage shift of devices.

Referring to FIG. 7, a schematic view of the thin film transistor substrate in a step S5 of the preparation method according to the embodiment 1 of the present disclosure is illustrated.

In step S5: disposing an interlayer dielectric layer 16, and providing a first via hole 161 on the interlayer dielectric layer 16.

The interlayer dielectric layer 16 is disposed by adopting a plasma enhanced chemical vapor deposition method or a sputtering method.

Referring to FIG. 8, a schematic view of the thin film transistor substrate in a step S6 of the preparation method according to the embodiment 1 of the present disclosure is illustrated.

In step S6: disposing a source/drain layer 17, and forming a pattern of the source/drain layer 17 after etching.

The light shielding layer 11 of the nano core-shell structure has poor conductivity and does not have a capacitive coupling effect with the source/drain layer 17. Two yellow light processes can be omitted, which introduce the source and the light shielding layer connection in the source/drain layer 17, thereby reducing the number of masks and reducing the cost.

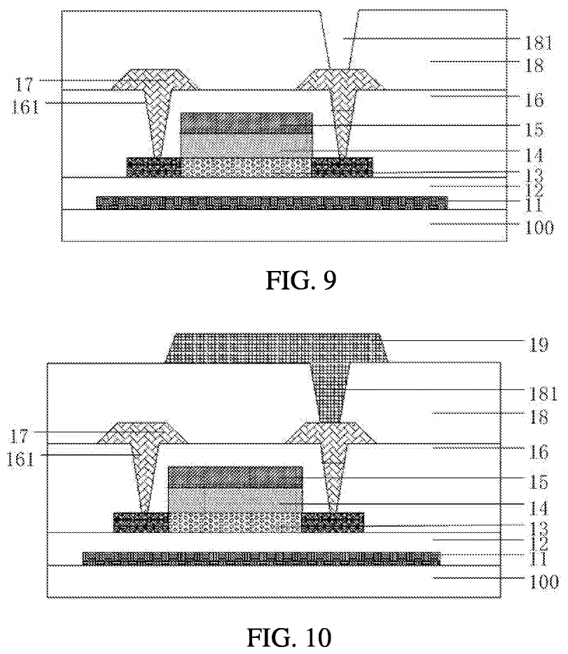

Referring to FIG. 9, a schematic view of the thin film transistor substrate in a step S7 of the preparation method according to the embodiment 1 of the present disclosure is illustrated.

In step S7: disposing a passivation layer 18, and providing a second via hole 181 on the passivation layer 18.

The passivation layer 18 is disposed by adopting a plasma enhanced chemical vapor deposition method or a sputtering method.

Referring to FIG. 10, a schematic view of the thin film transistor substrate in a step S8 of the preparation method according to the embodiment 1 of the present disclosure is illustrated.

In step S8: disposing a pixel electrode layer 19, and forming a pixel electrode by etching.

The present disclosure provides a thin film transistor substrate and a preparation method thereof. The light shielding layer is formed by a nano core-shell structure, wherein the light shielding layer of the nano core-shell structure has poor conductivity and does not have a capacitive coupling effect with the source/drain layer, thereby reducing the number of masks and reducing the cost. In addition, the light shielding layer of the nano core-shell structure can also absorb short-wavelength light and convert short-wavelength light into long-wavelength light. The short-wavelength leakage light does not reflect between the gate layer and the light shielding layer to reduce the threshold voltage negative bias caused by multiple reflections of leakage light in the active layer.

The present disclosure has been described with preferred embodiments thereof, and it is understood that many changes and modifications to the described embodiments can be carried out without departing from the scope and the spirit of the disclosure that is intended to be limited only by the appended claims.

What is claimed is:

1. A thin film transistor substrate, comprising:
a substrate layer, a light shielding layer, a buffer layer, an active layer, a gate insulating layer, a gate layer, an interlayer dielectric layer, a source/drain layer, a passivation layer, and a pixel electrode layer, which are sequentially disposed;
wherein the light shielding layer is formed by a nano core-shell structure, and the nano core-shell structure includes a nano core and a shell.

2. The thin film transistor substrate according to claim 1, wherein the nano core is a narrow band-gap semiconductor material, and the shell is an insulating dielectric material.

3. The thin film transistor substrate according to claim 1, wherein a band gap of the nano core is less than 2.5 eV, and a diameter range of the nano core is from 5 to 1000 nm.

4. The thin film transistor substrate according to claim 1, wherein a material of the nano core includes one of indium arsenide or indium phosphide.

5. The thin film transistor substrate according to claim 1, wherein a material of the shell includes one of silicon oxide or aluminum oxide.

6. The thin film transistor substrate according to claim 1, wherein a thickness range of the shell is from 3 to 200 nm.

7. The thin film transistor substrate according to claim 1, wherein the buffer layer completely covers the light shielding layer.

8. A preparation method of the thin film transistor substrate according to claim 1, comprising steps of:
step S1: providing a substrate and disposing on the substrate the light shielding layer of the nano core-shell structure;
step S2: placing the substrate and the light shielding layer of the nano core-shell structure in a vacuum for annealing;
step S3: disposing the buffer layer on the light shielding layer of the nano core-shell structure;
step S4: sequentially disposing the active layer, the gate insulating layer, and the gate layer on the buffer layer, and conducting a non-channel region of a pattern of the active layer;
step S5: disposing the interlayer dielectric layer, and providing a first via hole on the interlayer dielectric layer;
step S6: disposing the source/drain layer, and forming a pattern of the source/drain layer after etching;
step S7: disposing the passivation layer, and providing a second via hole on the passivation layer; and
step S8: disposing the pixel electrode layer, and forming a pixel electrode by etching.

9. The preparation method according to claim 8, wherein a pressure range of the vacuum is from 10⁻⁴ to 10³ Pa.

10. The preparation method according to claim 8, wherein a temperature range for annealing is from 100 to 500° C.

11. The preparation method according to claim 8, wherein the nano core is a narrow band-gap semiconductor material, and the shell is an insulating dielectric material.

12. The preparation method according to claim 8, wherein a band gap of the nano core is less than 2.5 eV, and a diameter range of the nano core is from 5 to 1000 nm.

13. The preparation method according to claim 8, wherein a material of the nano core includes one of indium arsenide or indium phosphide.

14. The preparation method according to claim 8, wherein a material of the shell includes one of silicon oxide or aluminum oxide.

15. The preparation method according to claim 8, wherein a thickness range of the shell is from 3 to 200 nm.

16. The preparation method according to claim 8, wherein the buffer layer completely covers the light shielding layer.
